(19) United States
(12) Patent Application Publication
(10) Pub. No.: US 2016/0139208 A1
(43) Pub. Date: May 19, 2016

(54) REMAINING BATTERY CAPACITY INDICATOR

(71) Applicant: Masahiro TSURUTA, Lomita, CA (US)

(72) Inventor: Masahiro TSURUTA, Lomita, CA (US)

(21) Appl. No.: 14/583,115

(22) Filed: Dec. 25, 2014

(30) Foreign Application Priority Data
Nov. 14, 2014 (JP) 2014-231161

(51) Int. Cl. G01R 31/36

(52) U.S. Cl. CPC G01R 31/3606

(57) ABSTRACT

A power supply path b (b1 to b6) is connected between a pair of positive and negative power terminals a1, a2. A first timer circuit c is connected to the power terminals a1, a2. The first timer circuit is initially on-state and interrupts the power supply path when a predetermined period of time has elapsed after electricity is conducted. A second timer circuit d is connected to the power supply path b via the first timer circuit. The second timer circuit is initially on-state and becomes off-state when a period of time determined according to a voltage between the power terminals has elapsed. Since a light emitting element e is connected to the power supply path via the second timer circuit, the light emitting element flashes when the second timer circuit is on-state, and the light emitting element is turned off when the second timer circuit becomes off-state.

### CROSS-REFERENCES TO RELATED APPLICATIONS

This patent specification is based on Japanese patent application, No. 2014-231161 filed on Nov. 14, 2014 in the Japan Patent Office, the entire contents of which are incorporated by reference herein.

### BACKGROUND OF THE INVENTION

1. Field of the Invention

The present invention relates to a remaining battery capacity indicator especially suitable for an electronic device with low power consumption.

2. Description of Related Art

An electric guitar (including an electronic bass and other instruments, the same applies hereafter) is often used by being connected with a guitar amplifier through a long cable. In recent years, various methods are proposed to connect the electric guitar with the guitar amplifier. As an example, a small-sized amplifier is connected to an output end of the electric guitar so that signals are output to the cable after the signal is adjusted or output impedance is decreased. As another example, a small-sized amplifier is included in the electric guitar itself or in a pickup of the electric guitar.

Concerning an indicator of a remaining battery capacity, Japanese Unexamined Patent Application Publication No. H06-189461, ECM-717 Service Manual, and ECM-330/360 Operating Instructions are disclosed. In Japanese Unexamined Patent Application Publication No. H06-189461, it is described in claim 2 and the paragraph 0023 that a remaining capacity of a battery is indicated for a predetermined period of time when a switch for indicating remaining battery capacity is pressed. In FIG. 3 and the paragraphs 0032 to 0034, a timer circuit using a transistor and a capacitor is described as an embodiment.

In ECM-330/360 Operating Instructions, it is described that the microphone has the battery check indicator, the indicator lights momentarily when the power switch is turned on, and the indicator lights dimly when the battery is weak.

In ECM-717 Service Manual, a circuit including a capacitor and a diode is described.

In AUDERE JZ3 Installation Instructions, an amplifier has an LED and the LED flashes three times when a power supply is turned on. The first and third flashes are bright and the second flash is a special flash to indicate a remaining battery capacity. The special flash indicates the remaining battery capacity by brightness. In addition, when the remaining battery capacity is further reduced, the LED blinks during the special flash. Although the brightness is decreased when the remaining battery capacity is reduced, the remaining battery capacity cannot be judged by a lighting duration (lighting time). Therefore, the LED should be specified to flash brightly before and after the special flash so as to indicate a standard brightness which is not affected by the remaining battery capacity. Furthermore, the LED is specified to blink when replacement of the battery is required.

For example, a current consumption of the small-sized amplifier used for the electric guitar is extremely lower than a current consumption of the LED. Therefore, if the LED is used for indicating the remaining battery capacity, the current consumption for indicating the remaining battery capacity becomes higher than the current consumption used for an original function of the amplifier.

On the other hand, when the LED indicates the remaining battery capacity only for a certain period of time without the first flash and the second flash such as the special flash, it is difficult to recognize that the remaining battery capacity is reduced.

In Japanese Unexamined Patent Application Publication No. H06-189461, although the remaining battery capacity is indicated for a certain period of time, a lighting duration is not changed depending on the remaining battery capacity. In ECM-717 Service Manual and ECM-330/360 Operating Instructions, when the power is turned on, the LED is flashed by instantly using electricity stored on a capacitor while the power is off. Therefore, a lighting duration is not used for indicating the remaining battery capacity.

In AUDERE JZ3 Installation Instructions, the LED is flashed at least three times and is blanked in some situations. Therefore, complicated control is required for indicating the remaining battery capacity. As a result, a circuit configuration is unavoidably complicated.

Thus, a remaining battery capacity indicator having a simple structure, being provided at a low cost, requiring low current consumption, and showing a battery condition easily is required.

The present invention provides a remaining battery capacity indicator that can more efficiently indicate a remaining battery capacity.

### BRIEF SUMMARY OF THE INVENTION

A remaining battery capacity indicator of the present invention comprises; a pair of positive and negative power terminals; a power supply path that is connected between the power terminals; a first timer circuit that is connected between the power terminals, is initially on-state, and interrupts the power supply path when a predetermined period of time has elapsed after electricity is conducted; a second timer circuit that is connected to the power supply path via the first timer circuit, is initially on-state, and becomes off-state when a period of time determined according to a voltage between the power terminals has elapsed; and a light emitting element that is connected to the power supply path via the second timer circuit. Note that “electricity is conducted” means a state that the battery is connected to the power terminals, the voltage is applied to the power terminals, and a predetermined current starts flowing.

In the remaining battery capacity indicator of the present invention, a period of time to keep the on-state is determined by the voltage between the power terminals. Therefore, a lighting duration of the light emitting element is determined according to the voltage between the power terminals. Consequently, the voltage between the power terminals can be recognized by a length of the lighting duration. Note that the voltage between the power terminals basically indicates the remaining battery capacity of the battery. Hereafter, the voltage between the power terminals is used in the same meaning. In addition, the power supply path itself is interrupted when a predetermined period of time has elapsed after electricity is conducted. Therefore, no power consumption is incurred after that.

In the present invention, the voltage between the power terminals can be recognized by the length of the lighting duration. In other words, the battery condition can be recognized by one flash. In order to indicate the change of the voltage only by the brightness or darkness, the standard brightness, which is the brightest state, should be indicated. Therefore, bright flash and dark flash should be indicated in order. Thus, such a case requires complicated control and is apparently different from the present invention that enables users recognize the voltage by the length of the lighting duration.

The present invention can realize a simple structure, a low cost, and an easy indication.

### BRIEF DESCRIPTION OF THE DRAWINGS

FIG. 1 is a block diagram showing a remaining battery capacity indicator concerning an embodiment of the present invention.

FIG. 2 is a block diagram showing a remaining battery capacity indicator concerning another embodiment of the present invention.

FIG. 3 is a block diagram showing a remaining battery capacity indicator concerning another embodiment of the present invention.

FIG. 4 is a circuit diagram showing a remaining battery capacity indicator concerning another embodiment of the present invention.

FIG. 5 is a circuit diagram showing a functionally separate state.

### DETAILED DESCRIPTION OF THE INVENTION

Hereafter, embodiments of the present invention will be explained referring the drawings.

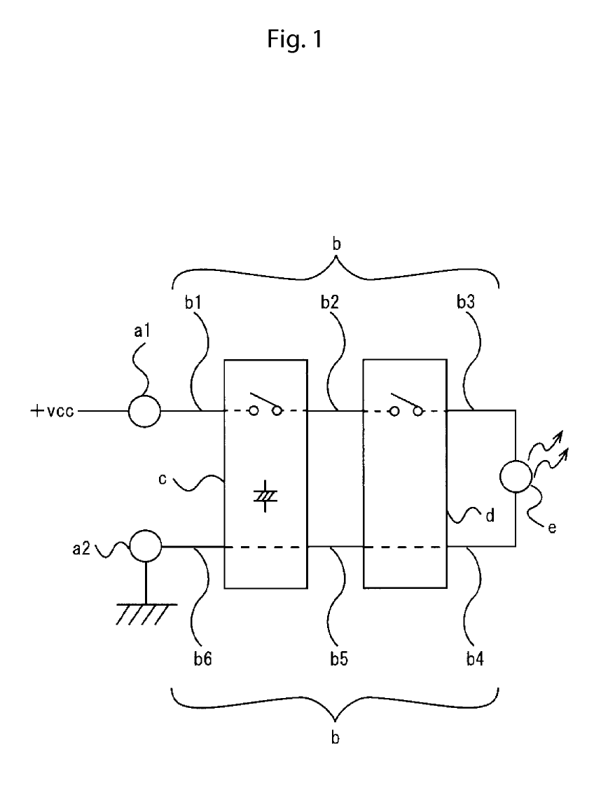

FIG. 1 shows a remaining battery capacity indicator concerning an embodiment of the present invention by a block diagram.

In the figure, the remaining battery capacity indicator has; a pair of positive and negative power terminals a1, a2; a power supply path b (b1 to b6) that is connected between the power terminals a1, a2; a first timer circuit c that is connected between the power terminals a1, a2, is initially on-state, and interrupts the power supply path b when a predetermined period of time has elapsed after electricity is conducted; a second timer circuit d that is connected to the power supply path b via the first timer circuit c, is initially on-state, and becomes off-state when a period of time determined according to a voltage between the power terminals a1, a2 has elapsed; and a light emitting element e that is connected to the power supply path b via the second timer circuit d.

Note that a switch for the remaining battery capacity indicator is not required. This is because the remaining battery capacity indicator is directory connected to the power terminals of an original circuit so that the remaining battery capacity is automatically indicated when the electricity is conducted to the original circuit and then the remaining battery capacity indicator is automatically turned off. In this point, the present invention is different from the technology that stores electricity while the power is off to use the electricity after the power is turned on. The device using the stored power is completed only by the stored power and is not connected in parallel with the power terminals of the original circuit.

In the above explained configuration, the power supply path b (b1 to b6) is connected between the pair of positive and negative power terminals a1, a2. The first timer circuit c is connected between the power terminals a1, a2. The first circuit c is initially on-state and interrupts the power supply path b when a predetermined period of time has elapsed after electricity is conducted. The second timer circuit d is connected to the power supply path b via the first timer circuit c. The second timer circuit d is initially on-state and becomes off-state when a period of time determined according to the voltage between the power terminals a1, a2 has elapsed. The light emitting element e is connected to the power supply path b via the second timer circuit d. Therefore, the light emitting element e flashes when the second timer circuit d is on-state, and the light emitting element e is turned off when the second timer circuit d becomes off-state.

In this case, a period of time to keep the on-state is changed according to the voltage between the power terminals a1, a2. Therefore, a lighting duration of the light emitting element e is determined depending on the voltage between the power terminals a1, a2. For example, the lighting duration is short when the voltage is high and the lighting duration is long when the voltage is low. Of course, the configuration can be reversed. Consequently, the voltage between the power terminals a1, a2 can be recognized by the length of the lighting duration. If the battery is connected to the power terminals a1, a2, the light emitting element e flashes for a short time (e.g. for only a moment) when the remaining battery capacity is enough, and the light emitting element e flashes for a long time when the remaining battery capacity is low. In case the light emitting element e is connected to the power supply path b and configured to flash brightly when the remaining battery capacity is enough and to flash dark when the remaining battery capacity is low, the light emitting element e flashes brightly for a short time when the remaining battery capacity is enough and the light emitting element e flashes darkly for a long time when the remaining battery capacity is low. Thus, users can certainly recognize the remaining battery capacity by using two kinds of indication methods: the darkness and the lighting duration, because the users are difficult to recognize the remaining battery capacity when judged only from the darkness of the light emitting element.

As described in the present embodiment, since the lighting duration is specified to be long when the brightness is dark, recognizability is enhanced. For example, when the remaining battery capacity is enough and the flash is bright, the users can sufficiently recognize the flash even if the light emitting element flashes only for a short time. On the other hand, when the remaining battery capacity is poor, the flash is usually overlooked easily because the flash is dark. By elongating the lighting duration, the light emitting element continues to indicate the situation that the remaining battery capacity is poor for a long time. Therefore, the users can easily recognize the situation.

In addition, the power supply path b itself is interrupted when the predetermined period of time has elapsed after electricity is conducted. Therefore, no power consumption is incurred after that. The power consumption can be interrupted not only for the second timer circuit d and the light emitting element e, but also for the first timer circuit c. By the above explained configuration, the remaining battery capacity is indicated just after electricity is conducted and no power consumption is incurred after that. Therefore, even when the power consumption of the original function is low, the battery life is not shortened by indicating the remaining battery capacity more than necessary.

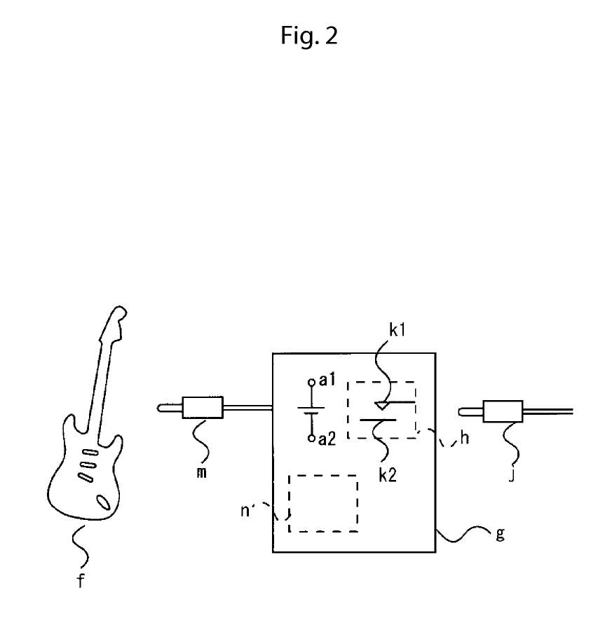

FIG. 2 shows a remaining battery capacity indicator concerning another embodiment of the present invention by a block diagram.

The present embodiment shows an example of the remaining battery capacity indicator applied for a small-sized amplifier g of an electric guitar f. The power terminals a1, a2 are power terminals of the amplifier g of the electric guitar f, which is an electronic stringed instrument. The amplifier g has a jack h as an output terminal. When a plug j is inserted into the jack h, switch contacts k1, k2 in the jack h are in contact with each other and a power supply is turned on through the switch contacts k1, k2. Although not shown in the figure, the circuit of the indicator shown in FIG. 1 is included in the amplifier g. On the amplifier g, another plug m is provided so as to be connected with the electric guitar f. A minute signal input from a pickup of the electric guitar f is amplified at an amplifying section n by a predetermined amplification rate, and then the amplified signal is output from the jack h to the plug j.

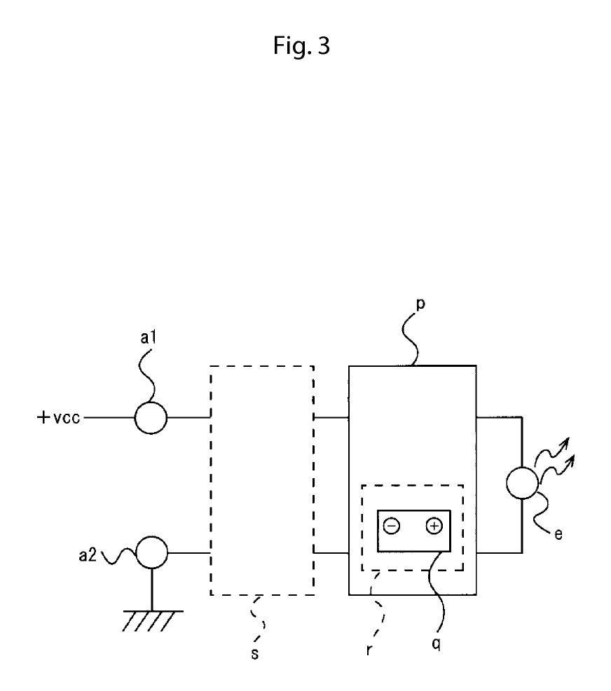

FIG. 3 shows a remaining battery capacity indicator concerning another embodiment of the present invention by a block diagram.

The remaining battery capacity indicator includes a pair of power terminals a1, a2, a light emitting element e that is connected between the power terminals a1, a2, and a lighting time adjustment circuit p.

In the remaining battery capacity indicator, when a second voltage V2 is lower than a first voltage V1, a brightness of the light emitting element is darker and a lighting duration of the light emitting element is longer when a voltage between the power terminals is the second voltage V2 than when the voltage between the power terminals is the first voltage V1. As an example of the above, the remaining battery capacity indicator has a charging circuit r that charges a power storage element q by the voltage between the power terminals a1, a2, and a lighting time adjustment circuit p that adjusts the lighting duration based on a charging time of the power storage element q of the charging circuit r.

When the power storage element q is charged by the voltage between the power terminals a1, a2 in the charging circuit r, the power storage element q is charged quickly if the voltage is high and the power storage element q is charged slowly if the voltage is low. The lighting time adjustment circuit p adjusts the lighting duration based on the charging time of the power storage element q of the charging circuit r. Therefore, when the second voltage V2 is lower than the first voltage V1, the lighting duration can be specified to be longer when the voltage between the power terminals a1, a2 is the second voltage V2 than when the voltage between the power terminals a1, a2 is the first voltage V1. In addition, when the voltage between the power terminals a1, a2 becomes lower, the brightness of the light emitting element e can be darker.

Furthermore, a power saving circuit s can be provided so as to interrupt the current consumption when a predetermined period of time has elapsed after electricity is conducted to the power terminals a1, a2. The power saving circuit s is same as the first timer circuit c.

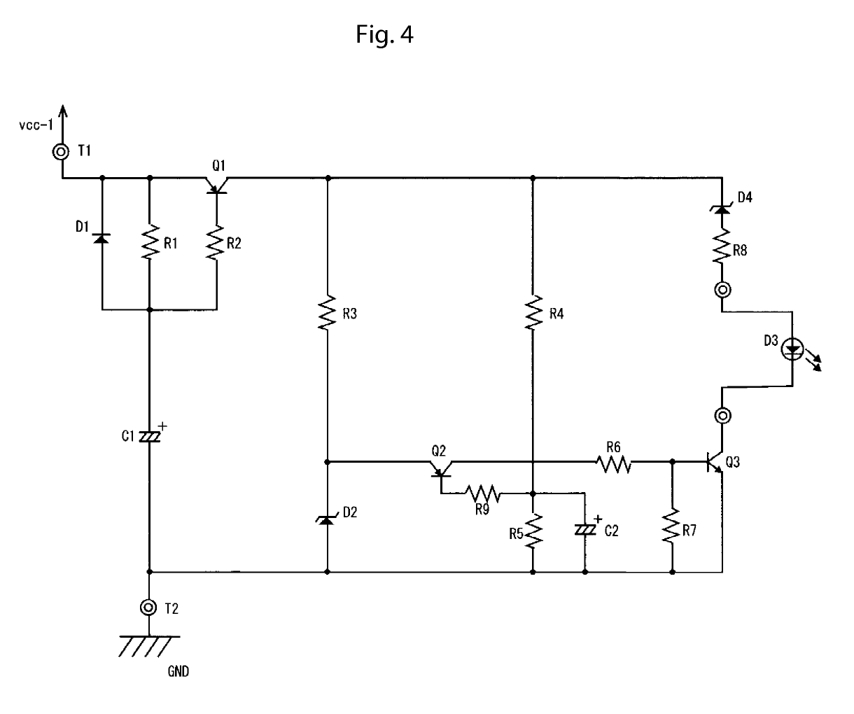

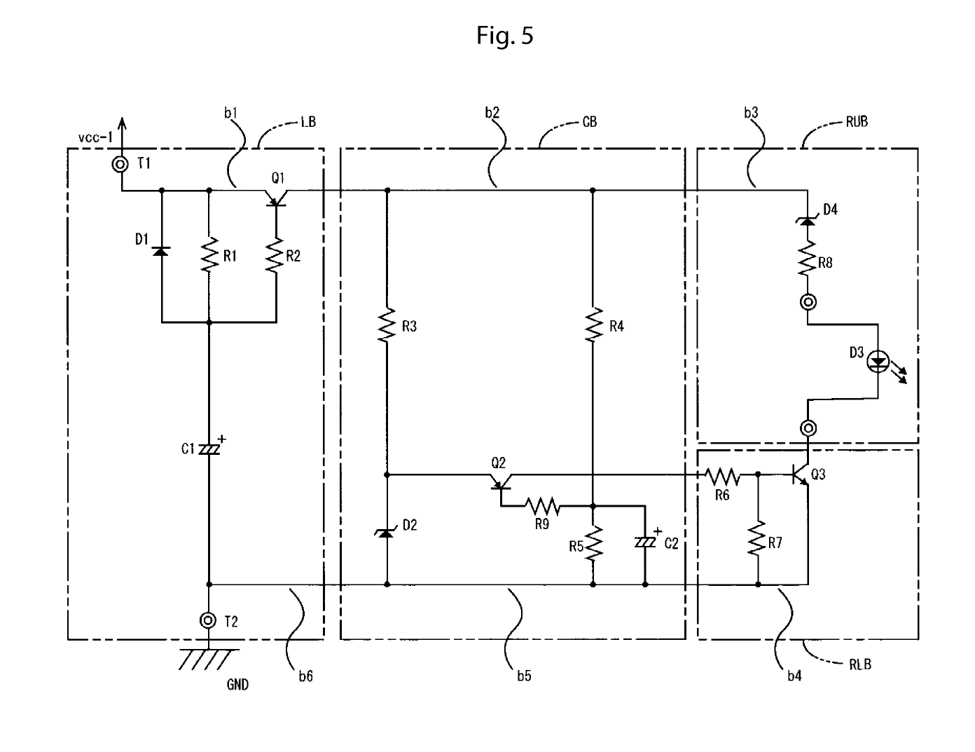

FIG. 4 shows a remaining battery capacity indicator concerning another embodiment of the present invention by a circuit diagram. FIG. 5 shows a functionally separate state by a circuit diagram. The circuits shown in FIG. 4 and FIG. 5 are same although FIG. 5 is functionally separated.

In the left block LB in FIG. 5, power terminals T1, T2 are provided. The power terminals T1, T2 correspond to the power terminals a1, a2. The power terminal T1 is connected to a not illustrated positive-side power supply (VCC). The power terminal T2 is connected to a negative side as a ground connection. The power supply path b (b1 to b6) is formed from the power terminals T1, T2. An emitter terminal of a PNP-type transistor (hereafter referred to merely as a transistor) Q1 is connected to the power terminal T1. A collector terminal of the transistor Q1 is connected to the power supply path b2. In other words, the emitter terminal and the collector terminal of the transistor Q1 are interposed in the power supply path b. Note that “the emitter terminal and the collector terminal are interposed” means a state that the power supply path b is separated and the emitter terminal and the collector terminal are connected respectively to both ends of the separated power supply path b. By the above explained configuration, a section between the emitter terminal and the collector terminal of the transistor Q1 functions as a part of the power supply path b.

In addition, a cathode of a diode D1 and one end of a resistor R1 are connected to the power terminal T1, and an anode of the diode D1 and another end of the resistor R1 are connected together and connected to a positive side terminal of an electrolytic capacitor C1, which corresponds to a first capacitor. A negative side terminal, which is another end terminal of the positive terminal, of the electrolytic capacitor C1 is connected to the power terminal T2 provided on a ground side. In other words, a parallel circuit composed of the diode D1 and the resistor R1 is connected in series with the electrolytic capacitor C1 between the power terminals T1, T2. By the above explained configuration, when a not illustrated battery is connected with the power terminals T1, T2 and electricity is conducted, the electrolytic capacitor C1 is charged through the resistor R1, and a voltage of a connection point between the resistor R1 and the anode of the diode D1 is gradually increased from a ground level finally to a voltage of the battery. For convenience of explanation, the voltage of the connection point is referred to as a terminal voltage of the electrolytic capacitor C1.

Although an electrolytic capacitor is used for convenience of explanation, other types of capacitors can be used instead (the same applies hereafter). In recent years, there are many ceramic capacitors of large capacity. Various capacitors including ceramic capacitors can be used for the present invention. The diode D1 is provided in order to allow the electrolytic capacitor C1 to be discharged more rapidly when the power supply is turned off, compared to a case where the electrolytic capacitor C1 is discharged through the resistor R1. Since the diode D1 is provided, the electrolytic capacitor C1 can be returned to an initial state rapidly.

The connection point between the resistor R1 and the anode of the diode D1 is connected to a base terminal of the transistor Q1 through a resistor R2. The resistor R2 can be arbitrarily selected according to a specification of the transistor Q1. Although the base terminal is pulled down to the ground level immediately after electricity is conducted, the voltage of the base terminal is gradually increased as the electrolytic capacitor C1 is charged and finally increased to the voltage of the battery. Although the transistor Q1 becomes on-state immediately after electricity is conducted, in the process of increasing the voltage, the transistor Q1 becomes off-state when the voltage reaches a certain level determined by a specification of the transistor Q1. Although a required time changed from the on-state to the off-state is determined by a resistance value of the resistor R1, a capacity of the electrolytic capacitor C1, and a voltage between the power terminals T1, T2, the required time substantially corresponds to the voltage between the power terminals T1, T2. In addition, if the voltage between the power terminals T1, T2 is high, a current flowing through the resistor R1 is large and the voltage of the base terminal of the transistor Q1 is increased rapidly. On the other hand, if the voltage between the power terminals T1, T2 is low, a current flowing through the resistor R1 is small and the voltage of the base terminal of the transistor Q1 is increased slowly.

As explained above, the transistor Q1 has a switching function and a current from the emitter terminal to the collector terminal is interrupted after the transistor Q1 becomes the off-state. By the above explained functions, the first timer circuit c is formed. In other words, the first timer circuit c interrupts the power supply path b between the emitter terminal and the collector terminal when the terminal voltage of the first capacitor (electrolytic capacitor C1), which is connected in series between the power terminals T1, T2, reaches a predetermined voltage that is determined based on the voltage between the power terminals T1, T2. Here, the predetermined voltage is a base voltage that makes the transistor Q1 become the off-state, or a base voltage that stops a base current flow.

Although a period of time before the transistor Q1 becomes the off-state is determined according to the voltage, the period of the time is long enough compared to a period of time before a state of a transistor Q2 explained below is changed. In other words, even when the period of time before the transistor Q1 becomes the off-state is the shortest, it is longer than a period of time that the second timer circuit changes from the on-state to the off-state.

Although the transistor Q1 is formed by the PNP-type transistor in the present embodiment, the transistor Q1 can be formed by a p-channel field effect transistor of an enhancement type, for example. In particular, if the transistor Q1 is formed by the p-channel field effect transistor of the enhancement type, when a potential difference between a source terminal and a gate terminal is 0, a path between the source terminal and a drain terminal can be surely shut off so as not to make a current flow. Of course, if the path between the source terminal and the drain terminal can be surely shut off in the future, other kinds of field effect transistors can be used. In such a case, the field effect transistor can be arranged by replacing the emitter terminal with the source terminal, replacing the collector terminal with the drain terminal, and replacing the base terminal with the gate terminal

As explained above, the first timer circuit c includes the PNP-type transistor (transistor Q1), the emitter terminal and the collector terminal of the PNP-type transistor are interposed in the power supply path b, the electrolytic capacitor C1, which corresponds to the first capacitor, forms a series circuit together with the resistor R1, the series circuit is connected between the power terminals T1, T2, a connection point between the electrolytic capacitor C1 and the resistor R1 is connected to the base terminal of the transistor Q1. Thus, the first timer circuit c provides a timer function. Note that the resistor R2 provided between the connection point and the base terminal is required depending on the specification of the transistor Q1.

In a center block CB of FIG. 5, a line connected to the collector terminal of the transistor Q1 corresponds to the power supply path b2, and a ground line connected to the power terminal T2 corresponds to the power supply path b5. At first, a series circuit formed by a resistor R3 and a zener diode D2, which corresponds to a first zener diode, is connected to the power supply paths b2, b5 so that a voltage of a connection point between the resistor R3 and the zener diode D2 becomes a reference voltage which is determined by a breakdown voltage of the zener diode D2. Then, a voltage dividing circuit formed by a series circuit of resistors R4, R5 is connected to the power supply paths b2, b5. Note that the voltage dividing circuit means a circuit that includes a plurality of elements having resistance components wherein the elements are connected in series and the elements divide the voltage according to a ratio of the resistance components. An electrolytic capacitor C2, which corresponds to a second capacitor, is connected in parallel with the resistor R5 connected at the ground side. When electricity is conducted between the power supply paths b2, b5 and the battery, the electricity is charged in the electrolytic capacitor C2 through the resistor R4. Since the electrolytic capacitor C2 is connected, a voltage of a connection point between the resistor R4 and the resistor R5 is initially kept at almost the ground level. As the electrolytic capacitor C2 is charged, the voltage of the connection point is increased up to a value which is determined by multiplying an original ratio of the resistor R4 and the resistor R5 by the voltage of the power supply paths b2, b5.

In addition, if an emitter terminal of a PNP-type transistor (hereafter, referred to merely as a transistor) Q2 is connected to a connection point between the zener diode D2 and the resistor R3 and a base terminal of the transistor Q2 is connected to a connection point between the resistor R4 and the resistor R5 through a resistor R9, the base terminal is initially pulled down to a side of the ground level and the transistor Q2 is on-state. After a predetermined period of time, which is determined by the voltage between the power supply paths b2, b5, a resistance value of the resistor R4 and a capacity of the electrolytic capacitor C2, has elapsed, the voltage of the base terminal of the transistor Q2 is increased. Thus, the base current is stopped flowing and the transistor Q2 is changed to off-state.

In other words, a series circuit that is formed by the resistor R3 and the first zener diode (zener diode D2) is provided. The series circuit is connected in series between the power terminals T1, T2. The voltage of the connection point between the resistor R3 and the first zener diode (zener diode D2) is used as a reference voltage. After electricity is conducted between the power terminals T1, T2, when a terminal voltage of the second capacitor (electrolytic capacitor C2) connected in series between the power terminals T1, T2 reaches the reference voltage, the transistor Q2 (corresponding to the third transistor) is changed from on-state to off-state. Therefore, by the above explained configuration, a timer function of the second timer circuit d is achieved. As for the second capacitor (electrolytic capacitor C2), specifically, a voltage dividing circuit of the resistor elements (R4, R5) is connected between the power terminals T1, T2, and the second capacitor (electrolytic capacitor C2) is connected in parallel with the resistor element (R5), which is one of the resistor elements of the voltage dividing circuit. In the above explanation, it is described that the transistor Q2 is changed from the on-state to the off-state when the terminal voltage of the electrolytic capacitor C2 reaches the reference voltage. However, the terminal voltage does not have to be strictly matched with the reference voltage. Depending on the circuit structure, the terminal voltage does not have to be matched with the reference voltage. However, the reference voltage, which is not affected by the remaining battery capacity, can be specified so that the transistor Q2 is changed from the on-state to the off-state when a predetermined relation is satisfied by comparing the terminal voltage with the reference voltage.

When the transistor Q2 is the on-state, a current that flows from the emitter terminal to the collector terminal functions as a control signal to control lighting of the LED.

In the right block of FIG. 5, an upper half block RUB corresponds to the light emitting element, and a lower half block RLB corresponds to a switching circuit of the light emitting element. By the switching circuit and the above described timer function, the second timer circuit d is formed.

The switching circuit is mainly realized by a switching operation of an NPN-type transistor (hereafter, referred to merely as a transistor) Q3. The transistor Q3 corresponds to the second transistor. When the transistor Q2 is the on-state, a current supplied from a collector terminal of the transistor Q2 is supplied to a base terminal of the transistor Q3 and a resistor R7 through a resistor R6. Thus, a predetermined potential is applied to the base terminal of the transistor Q3 and the transistor Q3 becomes on-state. When the transistor Q2 is the off-state, a current is not supplied from the collector terminal of the transistor Q2. Thus, the base terminal of the transistor Q3 is pulled down to the ground level, and the transistor Q3 becomes off-state. As explained above, the base terminal of the transistor Q3 is an input end of a control signal to switch the transistor Q3 between the on-state and the off-state. Therefore, the base terminal of the transistor Q3 is referred to as a switching terminal.

A light emitting diode (LED) D3, which corresponds to the light emitting element, is connected between the power supply path b3, which is a positive side, and the power supply path b4, which is a negative side, while interposing the transistor Q3 as a switching device. Because of characteristics of the light emitting diode D3, a current limiting resistance R8 is connected in series with the light emitting diode D3 so that a current having a predetermined current value flows. Although the light emitting diode (LED) is used because of a feature of low current consumption, the light emitting element is not limited to the light emitting diode. Any elements can be used as the light emitting element as long as the element has a function of emitting light when the voltage is applied and the current flows. In addition, the current limiting resistance R8 is required to form a circuit, and the current limiting resistance R8 can be adequately arranged.

In the present embodiment, in addition to the current limiting resistance R8 and the light emitting diode D3, a zener diode D4, which corresponds to a second zener diode, is arranged. The zener diode D4 functions mainly for adjusting a brightness of the light emitting diode D3. For example, when the battery connected between the power terminals T1, T2 is 9 V, the zener diode D4 can be effectively used so that the brightness becomes low enough when the remaining battery capacity is reduced. If a breakdown voltage of the zener diode D4 is specified to be 3 to 4 V, a voltage applied to the current limiting resistance R8 and the light emitting diode D3 is reduced by an amount of the breakdown voltage. In the present embodiment, in order to indicate the remaining battery capacity of the battery of 9 V, a resistance value of the current limiting resistance R8 is specified to be 1 kΩ. Therefore, if the breakdown voltage of the light emitting diode D3 is 3 to 4 V, the voltage applied to the current limiting resistance R8 and the light emitting diode D3 is 5 to 6 V, and the brightness of the light emitting diode D3 becomes dark when the remaining battery capacity is 5 to 6 V. In other words, if the breakdown voltage of the zener diode D4 is not existed, the brightness of the light emitting diode D3 hardly becomes dark even when the remaining battery capacity is reduced. Since the breakdown voltage of the zener diode D4 is existed, the brightness of the light emitting diode D3 can become dark in a relatively early stage when the remaining battery capacity is reduced and the light emitting diode D3 can be completely turned off in a certain stage. In other words, if the zener diode D4 is not provided, the light emitting diode D3 may not be turned off completely. Namely, if a power supply voltage is higher than a forward direction voltage of the light emitting diode D3, the light emitting diode D3 may emit light slightly. For example, the light emitting diode D3 may emit light even when the power supply voltage is approximately 3.5 V. The zener diode D4 functions efficiently to turn off the light completely at approximately 5.5 V.

Since the zener diode D4 adjusts the brightness as explained above, the zener diode D4 forms a brightness adjusting circuit that adjusts a brightness of the light emitting diode D3, which corresponds to the light emitting element, depending on the voltage between the power terminals T1, T2. Note that the brightness adjusting circuit is not limited to the zener diode. For example, a resistor element can be additionally connected in series with the light emitting element to make the brightness dark early because of voltage drop. As another example, a circuit to actively reduce the voltage applied to the light emitting element based on the voltage can be formed.

More specifically, a relation of the remaining battery capacity of the battery, the brightness and the lighting duration is as follows.

| Remaining | Brightness and | Guide for |
|---|---|---|
| battery capacity | lighting duration | battery exchange |
| 8.0 V | bright and short | not required |
| | (for about 1 second) | |
| 7.5 V | bright and short | usable without problem |
| | (for about 1 second) | |
| 7.0 V | slightly dark and long | usable |
| | (for about 3 seconds) | |
| 6.5 V | dark and long | usable but battery |
| | (for about 4 seconds) | exchange is recommended |
| 6.0 V | dark and long | usable but battery |
| | (for about 5 seconds) | exchange is recommended |
| 5.5 V | not lighted | battery exchange is |
| | | recommended |

As for the zener diode D4, in the present embodiment, the second zener diode (zener diode D4) is connected in series with the current limiting resistance R8 and the light emitting diode D3, and a voltage between the power terminals T1, T2 is absorbed by the second zener diode (zener diode D4) to apply a remaining voltage to the current limiting resistance R8 and the light emitting diode D3. Here, the light emitting diode D3 corresponds to the light emitting element, and the voltage between the power terminals T1, T2 corresponds to the power supply paths b3, b4.

As for the transistor Q3, the NPN-type transistor (transistor Q3), which corresponds to the second transistor as a switching device, is connected in series with the light emitting diode D3 so that the base terminal of the transistor Q3 functions as a switching terminal for on/off.

As for the transistor Q2, the collector terminal is connected to a connection point used as the reference voltage between the first zener diode (zener diode D2) and the resistor R3, the base terminal is connected to a connection point of a pair of resistor elements of the voltage dividing circuit formed by the resistor R4 and the resistor R5, and the emitter terminal is used as a current output end to output the current to the base terminal, which is a switching terminal, of the transistor Q3. Thus, the transistor Q2 forms the third transistor.

In the present embodiment, the light emitting element is the light emitting diode (LED) D3 that is connected in series with the current limiting resistance R8.

The above described remaining battery capacity indicator can be used, for example, for an amplifier of an electronic stringed instrument shown in FIG. 2. In this case, the power terminals T1, T2 are power terminals of the amplifier g of the electronic stringed instrument. In this case, the amplifier includes a jack h as an output terminal, and a power supply is turned on when the plug j is inserted into the jack h because predetermined switch contacts k1, k2 are in contact with each other.

The amplifier g is interposed between the electric guitar f and the plug j of the cable that is connected to the amplifier g. A power consumption of the amplifier used for such a purpose is generally tiny. For example, although a current value of the amplifier g is approximately 0.02 to 0.3 mA, a current consumption of the light emitting diode D3 is 1 mA or more, which is considerably larger than that of the amplifier. Therefore, it is not allowable that 1 mA or more of the current is used only for indicating the remaining battery capacity.

In the present embodiment, however, the second timer circuit finishes indicating the remaining battery capacity within 10 seconds, and the first timer circuit interrupts the power supply path b approximately 10 seconds after electricity is conducted. After that, no power consumption is required even for the light emitting diode D3. Therefore, it is fully allowable that several mA of current consumption is required only when indicating the remaining battery capacity.

In this case, the power terminals T1, T2 are connected to a battery of an electronic device (amplifier g) that requires tiny power consumption. The present embodiment is effective especially when the power consumption of the remaining battery capacity indicator is higher than the power consumption of the electronic device (amplifier g).

In the above described embodiment, a power supply is turned on when the plug is inserted into the jack, which is an output terminal of the amplifier. However, the present invention is not limited to such a configuration. For example, the following configuration is also possible: the electronic device is an amplifier of an electronic stringed instrument, the power terminals T1, T2 are connected to a battery of the amplifier, the amplifier has a plug as an input terminal, and electricity is conducted from the battery to the power terminals when the plug is connected to a pickup of the electronic stringed instrument. Furthermore, an amplifier and a battery can be included in an electric guitar, and electricity can be conducted from the battery to the amplifier when a plug of a cable is inserted into a jack of the electric guitar. In this case, electricity is conducted to the remaining battery capacity indicator simultaneously with the amplifier.

As explained above, the remaining battery capacity indicator of the present invention can work without affecting a circuit of a main device. Since the voltage to be checked is the power supply voltage, a noise is not generated to the circuit of the main device when the power is turned on. Therefore, there is no problem even if the remaining battery capacity indicator starts working simultaneously when the power is turned on.

The noise is a fatal disadvantage when used for an instrument.

For example, suppose that an oscillation circuit (LFO) for oscillating a triangular wave and a rectangular wave is made using two operational amplifiers. Generally, when an analog amplifier is formed using the operational amplifiers in a single power source, a half voltage of the power supply voltage is produced to be used as a pseudo ground (reference bias voltage). If the two circuits are simultaneously driven by the battery of 9 V and an output of the analog amplifier is connected to an external amplifier, a noise linked with an oscillation of the LFO may be generated from the external amplifier. This is because impedance of the power supply voltage and reference voltage that is used for the pseudo ground cannot be ideally low. In particular, the voltage of the pseudo ground is varied by a current change of the oscillation circuit and a sound is generated because of that. If the LED is controlled to blink, a noise is generated in accordance with on/off of the LED.

On the other hand, the reference voltage is normally produced by dividing the power supply voltage to keep a half of the power supply voltage even when the power supply voltage is reduced. Therefore, impedance becomes high at low frequency. Consequently, when the voltage of the battery is low, the impedance of the power supply voltage is high and the power supply voltage is easily varied. Even if an electrolytic capacitor of approximately 100 to 470 μF, for example, is connected in parallel with the battery to reduce the impedance of the power supply voltage, the above described problem cannot be solved. Consequently, in order to solve the above described problem, the amplifier of the original device should be stopped working while the power supply voltage is checked.

Furthermore, the present invention does not require any external signals such as a trigger signal. The remaining battery capacity indicator starts working when the power of the original device is turned on. Conversely, the remaining battery capacity indicator works for a predetermined period of time after the power is turned on. After that, only the original device works and no current flows though the circuit of the remaining battery capacity indicator because the circuit becomes off-state.

Although the present invention is applied to, for example, the amplifier of the electronic instrument in the above described embodiment, it goes without saying that the present invention is generally suitable for any devices using a battery to indicate a remaining capacity of the battery. Even when the power consumption of the device to which the remaining battery capacity indicator is applied is lower than the power consumption of the original device, a power-saving effect can be obtained because the remaining battery capacity indicator starts working simultaneously when the power is turned on and no current is consumed after the predetermined period of time has elapsed.

A time that the first timer circuit and the second timer circuit are working is changed mainly by a remaining battery capacity. Of course, the time is affected by other elements of an electronic circuit. Nevertheless, it can be said that the time is changed mainly according to a remaining battery capacity.

Note that, this invention is not limited to the above-mentioned embodiments. Although it is to those skilled in the art, the following are disclosed as the one embodiment of this invention.

Mutually substitutable members, configurations, etc. disclosed in the embodiment can be used with their combination altered appropriately.

Although not disclosed in the embodiment, members, configurations, etc. that belong to the known technology and can be substituted with the members, the configurations, etc. disclosed in the embodiment can be appropriately substituted or are used by altering their combination.

Although not disclosed in the embodiment, members, configurations, etc. that those skilled in the art can consider as substitutions of the members, the configurations, etc. disclosed in the embodiment are substituted with the above mentioned appropriately or are used by altering its combination.

What is claimed is:

1. A remaining battery capacity indicator, comprising:
a pair of positive and negative power terminals;
a power supply path that is connected between the power terminals;
a first timer circuit that is connected between the power terminals, is initially on-state, and interrupts the power supply path when a predetermined period of time has elapsed after electricity is conducted;
a second timer circuit that is connected to the power supply path via the first timer circuit, is initially on-state, and becomes off-state when a period of time determined according to a voltage between the power terminals has elapsed; and
a light emitting element that is connected to the power supply path via the second timer circuit.

2. The remaining battery capacity indicator according to claim 1, wherein
the first timer circuit includes a first capacitor that is connected in series between the power terminals, and
the first timer circuit interrupts the power supply path when a terminal voltage of the first capacitor reaches a predetermined voltage.

3. The remaining battery capacity indicator according to claim 2, wherein
the first timer circuit includes a PNP-type transistor,
an emitter terminal and a collector terminal of the PNP-type transistor are interposed in the power supply path,
the first capacitor forms a series circuit together with a resistor, the series circuit is connected between the power terminals, and
a connection point between the first capacitor and the resistor is connected to a base terminal of the PNP-type transistor.

4. The remaining battery capacity indicator according to claim 1, wherein
the second timer circuit includes a second capacitor that is connected in series between the power terminals, and
the second timer circuit becomes off-state when a terminal voltage of the second capacitor reaches a predetermined reference voltage.

5. The remaining battery capacity indicator according to claim 4, wherein
the second timer circuit includes a series circuit that is formed by a resistor and a first zener diode,
the series circuit is connected between the power terminals, and a voltage of a connection point between the resistor and the first zener diode is the reference voltage.

6. The remaining battery capacity indicator according to claim 4, wherein
the second timer circuit includes a voltage dividing circuit that is formed by resistor elements,
the voltage dividing circuit is connected between the power terminals, and the second capacitor is connected in parallel with one of the resistor elements of the voltage dividing circuit.

7. The remaining battery capacity indicator according to claim 1, wherein
a second zener diode is connected in series with the light emitting element, and
a voltage between the power terminals is absorbed by the second zener diode to apply a remaining voltage to the light emitting element.

8. The remaining battery capacity indicator according to claim 1, wherein
the second timer circuit includes a second transistor that is used as a switching device,
the second transistor is connected in series with the light emitting element, and
a base terminal of the second transistor is used as a switching terminal to switch turning on and off the second timer circuit.

9. The remaining battery capacity indicator according to claim 6, wherein
the second timer circuit includes a second transistor that is used as a switching device,
the second transistor is connected in series with the light emitting element,
a base terminal of the second transistor is used as a switching terminal to switch turning on and off the second timer circuit,
a collector terminal of the third transistor is connected to the connection point that is used as the reference voltage,
a base terminal of the third transistor is connected to a connection point between a pair of the resistor elements of the voltage dividing circuit, and
an emitter terminal of the third transistor is a current output end to output a current to the switching terminal.

10. The remaining battery capacity indicator according to claim 1, wherein
the power terminals are power terminals of an amplifier of an electronic stringed instrument,
the amplifier includes a jack as an output terminal, and
a power supply is turned on when a plug is inserted into the jack.

11. The remaining battery capacity indicator according to claim 1, wherein
the power terminals are connected to a battery of an electronic device that requires tiny power consumption.

12. The remaining battery capacity indicator according to claim 11, wherein
the electric device is an amplifier of an electronic stringed instrument,
the power terminals are connected to a battery of the amplifier,
the amplifier includes a plug as an input terminal, and
the electricity is conducted from the battery to the power terminals when the plug is connected to a pickup of the electronic stringed instrument.

13. The remaining battery capacity indicator according to claim 11, wherein
a current consumption of the remaining battery capacity indicator is larger than a current consumption of the electric device.

14. The remaining battery capacity indicator according to claim 1, wherein
the light emitting element is an LED that is connected in series with a current limiting resistance.

15. A remaining battery capacity indicator, comprising:
a pair of power terminals; and
a light emitting element that is connected between the power terminals, wherein
when a second voltage is lower than a first voltage, a brightness of the light emitting element is darker and a lighting duration of the light emitting element is longer when a voltage between the power terminals is the second voltage than when the voltage between the power terminals is the first voltage.

16. The remaining battery capacity indicator according to claim 15, further comprising:
a charging circuit that charges a power storage element by the voltage between the power terminals; and
a lighting duration adjustment circuit that adjusts the lighting duration based on a charging time of the power storage element of the charging circuit.

17. The remaining battery capacity indicator according to claim 15, further comprising:
a power saving circuit that interrupts a current consumption when a predetermined period of time has elapsed after electricity is conducted.
